(19) United States
(12) Patent Application Publication
(10) Pub. No.: US 2026/0052784 A1
(43) Pub. Date: Feb. 19, 2026

(54) PIXEL IMPLANT GEOMETRIES FOR HIGH-PERFORMANCE PHOTODETECTORS

(71) Applicant: Raytheon Company, Tewksbury, MA (US)

(72) Inventors: Jamal I. Mustafa, Goleta, CA (US); Chad W. Fulk, Ventura, CA (US); David R. Rhiger, Santa Barbara, CA (US)

(21) Appl. No.: 18/808,774

(22) Filed: Aug. 19, 2024

(51) Int. Cl. H01L 27/146; H01L 31/0224; H01L 31/103; H01L 31/18

(52) U.S. Cl. CPC H10F 39/8027; H10F 30/2212; H10F 71/1253; H10F 77/206

(57) ABSTRACT

A system includes a focal planar array having multiple pixels. Each of at least some of the pixels includes a semiconductor substrate and a pixel formed in or over the semiconductor substrate, where the pixel includes a first implant having a first doping concentration and a second implant within the first implant. The second implant has a different width and/or depth than the first implant and a second doping concentration higher than the first doping concentration.

### TECHNICAL FIELD

This disclosure relates generally to imaging devices. More specifically, this disclosure relates to pixel implant geometries for high-performance photodetectors.

### BACKGROUND

Imaging systems often use digital pixels to capture information when generating images. For example, in each digital pixel, an electrical current from a photodetector can be used to charge an integration capacitor during a sampling period, and the voltage stored on the integration capacitor can be compared to a reference voltage. When the reference voltage is met or exceeded, the integration capacitor can be discharged. At that point, the electrical current from the photodetector can again be used to charge the integration capacitor. The number of times that the integration capacitor is charged and reset during the sampling period can be counted and used to generate image data for that digital pixel. This process can be performed for each digital pixel in an imaging array in order to generate image data for the array.

### SUMMARY

This disclosure relates to pixel implant geometries for high-performance photodetectors.

In a first embodiment, an apparatus includes a semiconductor substrate and a pixel formed in or over the semiconductor substrate. The pixel includes a first implant having a first doping concentration and a second implant within the first implant. The second implant has a different width and/or depth than the first implant and a second doping concentration higher than the first doping concentration.

Any single one or any combination of the following features may be used with the first embodiment. The pixel may include one or more ohmic contacts. The second doping concentration may provide ohmic contact for the pixel. The first implant may be configured to assist carrier collection, maintain quantum efficiency, and improve modulation transfer function (MTF) performance of the pixel. Dimensions of the first and second implants may be selected to tailor an electric field profile within the pixel. Dimensions of the pixel may be selected to reduce generation-recombination (GR) currents within the pixel. Dimensions of the pixel may be selected to reduce a depletion size and a depletion magnitude of the pixel.

In a second embodiment, a system includes a focal planar array having multiple pixels. Each of at least some of the pixels includes a semiconductor substrate and a pixel formed in or over the semiconductor substrate, where the pixel includes a first implant having a first doping concentration and a second implant within the first implant. The second implant has a different width and/or depth than the first implant and a second doping concentration higher than the first doping concentration.

Any single one or any combination of the following features may be used with the second embodiment. Each of the at least some of the pixels may include one or more ohmic contacts. For each of the at least some of the pixels, the second doping concentration may provide ohmic contact for the pixel. For each of the at least some of the pixels, the first implant may be configured to assist carrier collection, maintain quantum efficiency, and improve MTF performance of the pixel. For each of the at least some of the pixels, dimensions of the first and second implants may be selected to tailor an electric field profile within the pixel. For each of the at least some of the pixels, dimensions of the pixel may be selected to reduce GR currents within the pixel. For each of the at least some of the pixels, dimensions of the pixel may be selected to reduce a depletion size and a depletion magnitude of the pixel.

In a third embodiment, a method of forming a pixel includes obtaining a semiconductor substrate. The method also includes performing a first implantation to form a first doped region of the substrate. The method further includes performing a second implantation to form a second doped region of the substrate. The second doped region is positioned within the first doped region after formation of the doped regions. The first doped region has a different width and/or depth than the second doped region, and the second doped region has a higher doping concentration than the first doped region.

Any single one or any combination of the following features may be used with the third embodiment. The method may include forming one or more ohmic contacts for the pixel. The doping concentration of the second doped region may provide ohmic contact for the pixel. The first implant may be configured to assist carrier collection, maintain quantum efficiency, and improve MTF performance of the pixel. Dimensions of the first and second implants may be selected to tailor an electric field profile within the pixel. Dimensions of the pixel may be selected to reduce GR currents within the pixel. Dimensions of the pixel may be selected to reduce a depletion size and a depletion magnitude of the pixel.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example system supporting the use of a pixel array according to this disclosure;

FIG. 2 illustrates an example pixel implant geometry for a high-performance photodetector according to this disclosure;

FIGS. 3A through 3G illustrate example cross-sections of a high-performance photodetector during fabrication according to this disclosure; and

FIG. 4 illustrates an example method for fabricating a high-performance photodetector according to this disclosure.

### DETAILED DESCRIPTION

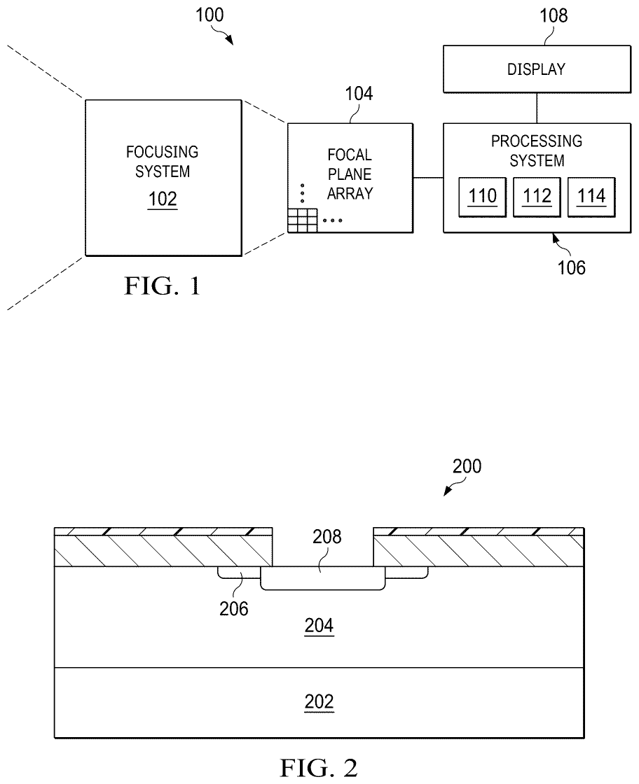

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, imaging systems often use digital pixels to capture information when generating images. For example, in each digital pixel, an electrical current from a photodetector can be used to charge an integration capacitor during a sampling period, and the voltage stored on the integration capacitor can be compared to a reference voltage. When the reference voltage is met or exceeded, the integration capacitor can be discharged. At that point, the electrical current from the photodetector can again be used to charge the integration capacitor. The number of times that the integration capacitor is charged and reset during the sampling period can be counted and used to generate image data for that digital pixel. This process can be performed for each digital pixel in an imaging array in order to generate image data for the array.

Unfortunately, when fabricating pixels in a semiconductor device, there can often be dislocations of materials within the semiconductor device. These dislocations represent defects in the semiconductor device that can affect the device's performance. For example, the dislocations may increase dark currents and reduce quantum efficiency (QE) of the pixels. As a particular example, dislocations may routinely occur in the depletion regions of photodiodes, and these defects can lead to increased carrier generation rates, which increases dark currents. While reducing the size of pixel implants can help to reduce the depletion region size, the resulting electric field profiles can lead to decreased quantum efficiency and modulation transfer function (MTF) of the pixels.

These types of problems can be particularly problematic for semiconductor devices fabricated using certain types of materials. For example, pixels fabricated using mercury-cadmium telluride (HgCdTe) on silicon (Si) may have larger dark currents due to higher dislocation densities compared to pixels fabricated using HgCdTe on cadmium zinc telluride (CZT). As a result, device performance at shorter wavelengths and lower temperatures may be limited due to dark current generation in the depletion regions of the pixels.

This disclosure provides pixel implant geometries for high-performance photodetectors. As described in more detail below, a pixel can be formed in or on a semiconductor substrate. The pixel includes a first implant having a first doping concentration. The pixel also includes a second implant within the first implant, where the second implant has a different width and/or depth than the first implant and a second doping concentration higher than the first doping concentration.

These types of pixel implant geometries can be used to reduce depletion region size and magnitude to help mitigate the effects of dislocations. This is achieved using a dual-implant geometry that includes a smaller (highly-doped) region and a larger (diffuse lower-doped) halo implant region. In some cases, the smaller implant region can provide ohmic contact for the pixel. Also, in some cases, the larger implant region can set up an electric field to assist carrier collection and maintain good quantum efficiency and modulation transfer function. As a result, these pixel implant geometries can be used to enable more effective fabrication and use of pixels, such as in focal plane arrays or other imaging systems.

FIG. 1 illustrates an example system 100 supporting the use of a pixel array according to this disclosure. As shown in FIG. 1, the system 100 includes a focusing system 102, a focal plane array 104, and a processing system 106. The focusing system 102 generally operates to focus illumination from a scene onto the focal plane array 104. The focusing system 102 may have any suitable field of view that is directed onto the focal plane array 104. The focusing system 102 includes any suitable structure(s) configured to focus illumination, such as one or more lenses, mirrors, or other optical devices.

The focal plane array 104 generally operates to capture image data related to a scene. For example, the focal plane array 104 may include a matrix or other collection of digital pixels that generate and process electrical signals representing a scene. Several of the digital pixels are shown in FIG. 1, although the size of the digital pixels is exaggerated for convenience here. The focal plane array 104 may capture image data in any suitable spectrum or spectra, such as in the visible, infrared, or ultraviolet spectrum. The focal plane array 104 may also have any suitable resolution, such as when the focal plane array 104 includes a collection of approximately 1,000 digital pixels by approximately 1,000 digital pixels (although other collection sizes may be used). The focal plane array 104 includes any suitable collection of digital pixels configured to capture image data. The focal plane array 104 may also include additional components that facilitate the receipt and output of information, such as read-out integrated circuits (ROICs). In some embodiments, the focal plane array 104 may represent a repartitioned digital pixel array that separates the front-end circuits of the digital pixels from the back-end circuits of the digital pixels.

The digital pixels of the focal plane array 104 include photodetectors that capture illumination from a scene and generate electrical currents. For each digital pixel, the electrical current can be used to charge an integration capacitor, and a voltage stored on the integration capacitor can be compared to a reference voltage by a comparator. The comparator can detect when the voltage stored on the integration capacitor meets or exceeds the reference voltage, at which point the integration capacitor can be reset. A counter or other accumulator can be used to count the number of times that the integration capacitor is charged and reset during each of one or more sampling periods. At least some of the photodetectors in the focal plane array 104 can have one of the pixel implant geometries described below, which can help to improve the operation of those photodetectors in the focal plane array 104.

The processing system 106 receives outputs from the focal plane array 104 and processes the information. For example, the processing system 106 may process image data generated by the focal plane array 104 in order to generate visual images for presentation to one or more personnel, such as on a display 108. However, the processing system 106 may use the image data generated by the focal plane array 104 in any other suitable manner.

The processing system 106 includes any suitable structure configured to process information from a focal plane array or other imaging system. For instance, the processing system 106 may include one or more processing devices 110, such as one or more microprocessors, microcontrollers, digital signal processors, field programmable gate arrays, application specific integrated circuits, or discrete logic devices. The processing system 106 may also include one or more memories 112, such as a random access memory, read only memory, hard drive, Flash memory, optical disc, or other suitable volatile or non-volatile storage device(s). The processing system 106 may further include one or more interfaces 114 that support communications with other systems or devices, such as a network interface card or a wireless transceiver facilitating communications over a wired or wireless network or a direct connection. The display 108 includes any suitable device configured to graphically present information.

Although FIG. 1 illustrates one example of a system 100 supporting the use of a pixel array, various changes may be made to FIG. 1. For example, various components in FIG. 1 may be combined, further subdivided, replicated, omitted, or rearranged and additional components may be added according to particular needs. Also, FIG. 1 illustrates one example type of system in which pixel implant geometries for high-performance photodetectors may be used. However, the pixel implant geometries may be used in any other suitable device or system.

FIG. 2 illustrates an example pixel implant geometry 200 for a high-performance photodetector according to this disclosure. For ease of explanation, the pixel implant geometry 200 may be described as being used in the pixels of the focal plane array 104 within the system 100 of FIG. 1. However, the pixel implant geometry 200 may be used with any suitable pixel or pixels in any suitable device or system.

As shown in FIG. 2, the pixel implant geometry 200 is formed in or over a semiconductor substrate 202. The semiconductor substrate 202 represents a silicon substrate, a CZT substrate, or other semiconductor substrate in or over which other components of the pixel implant geometry 200 can be formed. In some cases, the semiconductor substrate 202 may include at least one additional layer 204 of material over the underlying silicon, CZT, or other semiconductor material. For instance, the at least one additional layer 204 may include a layer of mercury-cadmium telluride (HgCdTe).

The pixel implant geometry 200 also includes a first implant 206 and a second implant 208. The first implant 206 represents a halo implant that is larger than the second implant 208 and that typically surrounds the second implant 208. The second implant 208 represents a pixel contact implant that can be electrically coupled to an external component, such as by using a metal or other conductive via or other conductive structure formed over and in contact with the second implant 208. As can be seen here, in some embodiments, the second implant 208 has a width (measured laterally) that is smaller compared to the width of the first implant 206, so the second implant 208 fits within the first implant 206. The second implant 208 is also more doped compared to the first implant 206, so the second implant 208 has a higher doping concentration than the doping concentration of the first implant 206.

The first implant 206 is a lower-doped region that yields a smaller magnitude of depletion in its surrounding region compared to the second implant 208. As a result, during operation, the first implant 206 generally operates to produce an electric field, increasing carrier collection and MTF while reducing carrier diffusion between adjacent pixels. The second implant 208 is a smaller higher-doped region compared to the first implant 206. As a result, during operation, the second implant 208 generally operates as the most conductive region of a photodetector. In some embodiments, the second implant 208 can provide ohmic contact for the photodetector when the second implant 208 includes a high doping concentration. The high conductivity of the second implant 208 allows for current to flow more easily between the photodetector and an external component.

Each of the first and second implants 206 and 208 may be fabricated using any suitable material(s). For example, in some embodiments, the semiconductor substrate 202 represents a silicon or CZT substrate, the additional layer 204 represents an HgCdTe layer, and each of the first and second implants 206 and 208 may be formed by depositing arsenic within the HgCdTe layer. Any suitable deposition process may be used here, such as ion implantation. In these cases, the first implant 206 may be formed by depositing arsenic ions slower or over a shorter period of time, and the second implant 208 may be formed by depositing arsenic ions faster or over a longer period of time. Note, however, that the different doping concentrations of the first and second implants 206 and 208 may be obtained in any suitable manner. Also note that the first and second implants 206 and 208 may be formed in any suitable order, so the second implant 208 may be formed before or after formation of the first implant 206.

It should be noted that while the first implant 206 has been described as being wider than the second implant 208, other shapes and sizes of the implants 206 and 208 may be used. For example, in other embodiments, the implants 206 and 208 may have different depths. In the example of FIG. 2, for instance, the second implant 208 is shown as being somewhat deeper than the first implant 206. In other cases, the second implant 208 may be significantly deeper than the first implant 206. As other examples, the first implant 206 may be somewhat deeper than the second implant 208, or the first implant 206 may be significantly deeper than the second implant 208. A combination of different widths and different depths may also be used with the implants 206 and 208.

The specific dimensions of the first and second implants 206 and 208 can be tailored to meet specific requirements in any given implementation. For example, the width and/or depth of the first implant 206 can affect the spacing between adjacent pixels in a focal plane array 104 or other device, so that width and/or depth may be selected based on the desired resolution of the device and the available space. The widths and/or depths of the first and second implants 206 and 208 can also affect the quantum efficiency of the photodetector for certain wavelengths. As a particular example, when the width of the first implant 206 ranges between about 4.0 microns to about 6.0 microns and the width of the second implant 208 ranges between about 2.0 microns to about 5.0 microns, there may be a significant improvement in quantum efficiency for wavelengths in a range between about 2.0 microns to about 4.75 microns. Improvements in MTF performance can also be shown for pixels having the same or similar dimensions. Overall, it is generally possible to select dimensions of the first and second implants 206 and 208 to tailor an electric field profile within each pixel, select dimensions of each pixel to reduce generation-recombination (GR) currents within each pixel, and/or select dimensions of each pixel to reduce a depletion size and a depletion magnitude of each pixel.

Although FIG. 2 illustrates one example of a pixel implant geometry 200 for a high-performance photodetector, various changes may be made to FIG. 2. For example, the relative sizes, shapes, dimensions, and doping concentrations of the first and second implants 206 and 208 can vary depending on the implementation.

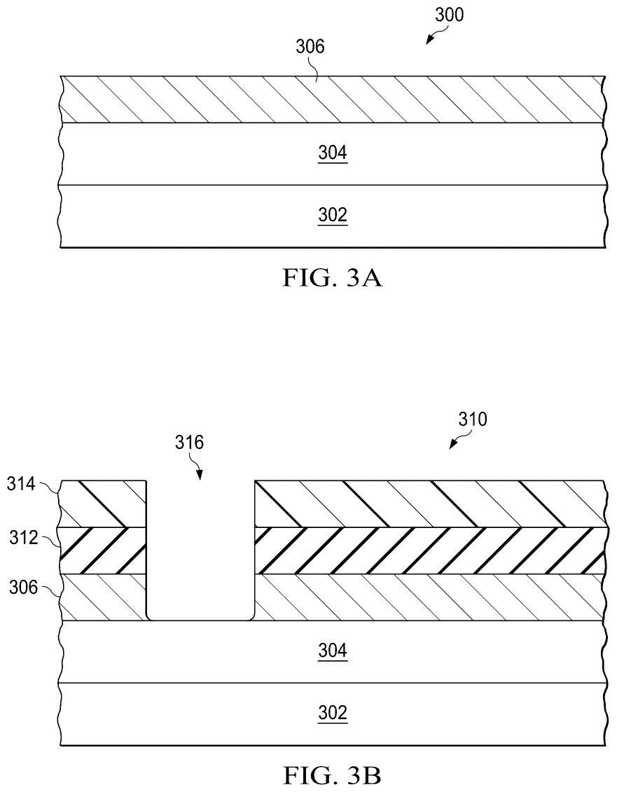

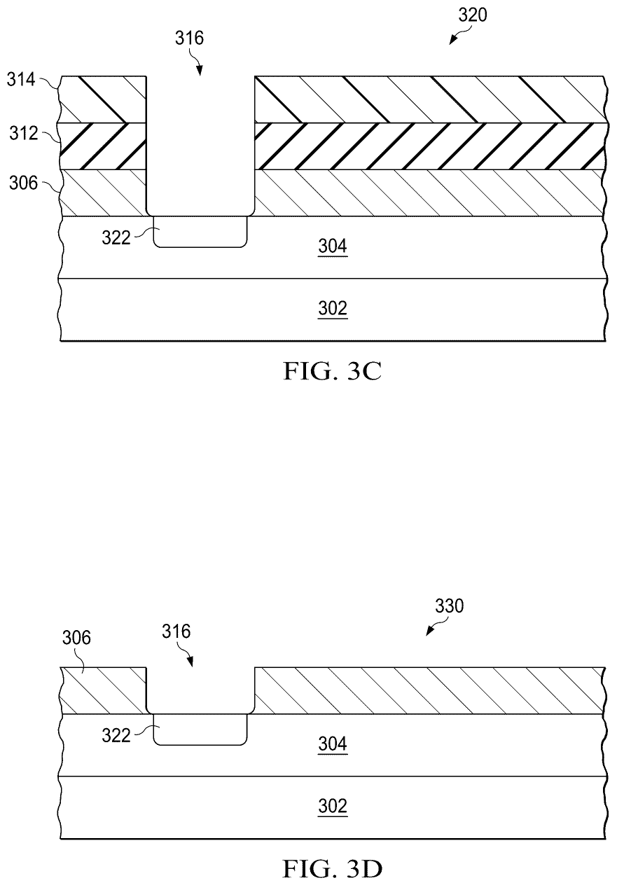

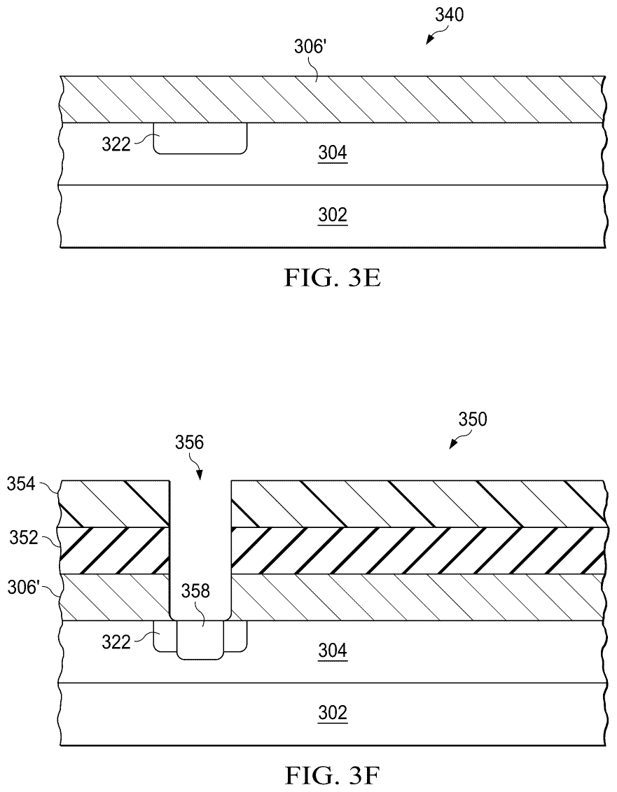

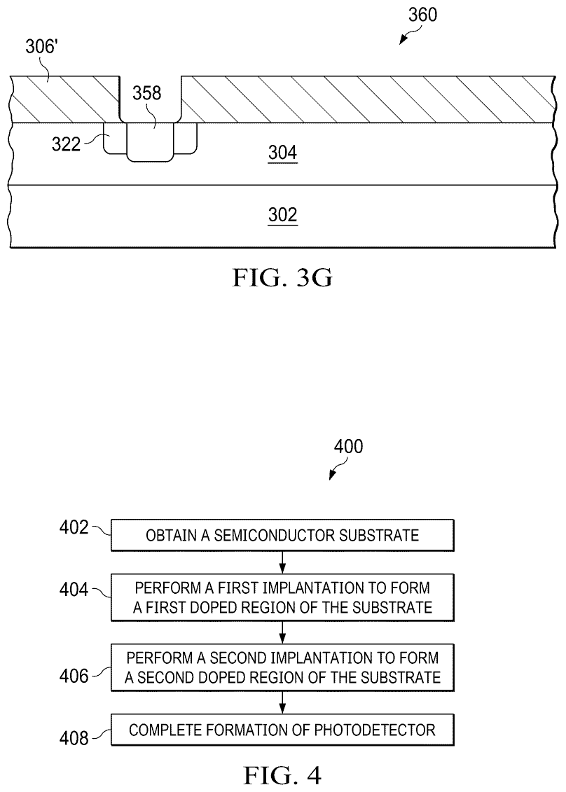

FIGS. 3A through 3G illustrate example cross-sections of a high-performance photodetector during fabrication according to this disclosure. More specifically, FIGS. 3A through 3G illustrate example cross-sections during fabrication of the pixel implant geometry 200 in the high-performance photodetector.

As shown in FIG. 3A, a cross-section 300 includes a semiconductor substrate 302, which may represent at least a portion of the semiconductor substrate 202 described above. A mercury-cadmium telluride (HgCdTe) layer 304 is formed over the semiconductor substrate 302. The HgCdTe layer 304 may represent at least a portion of the additional layer 204 described above. A cadmium telluride (CdTe) layer 306 is formed over the HgCdTe layer 304. Each layer 304 and 306 may be formed in any suitable manner, and each layer 304 and 306 may have any suitable thickness.

As shown in FIG. 3B, a cross-section 310 indicates that a silicon nitride (SiN) layer 312 is formed over the CdTe layer 306 and that a mask layer 314 is formed over the SiN layer 312. Each layer 312 and 314 may be formed in any suitable manner, and each layer 312 and 314 may have any suitable thickness. In this example, an opening 316 is formed through the mask layer 314, the SiN layer 312, and the CdTe layer 306, such as by using one or more etching operations. In some cases, the mask layer 314 can represent a photoresist layer that is patterned to form the opening 316 in the mask layer 314. A dry etch or other etch can be used to etch through the SiN layer 312, and another dry etch or other etch can be used to etch through the CdTe layer 306. This results in a portion of the HgCdTe layer 304 being exposed within the opening 316.

As shown in FIG. 3C, a cross-section 320 indicates that an implant 322 is formed in the HgCdTe layer 304 through the opening 316. In some embodiments, the implant 322 may represent a low-doped arsenic implant. In this example, the implant 322 is a wider implant. As shown in FIG. 3D, a cross-section 330 indicates that the SiN layer 312 and the mask layer 314 have been removed, such as by stripping. As shown in FIG. 3E, a cross-section 340 indicates that a CdTe layer 306′ has been formed, such as by depositing CdTe within the opening 316 and possibly on top of the remaining CdTe layer 306.

As shown in FIG. 3F, a cross-section 350 indicates that various earlier steps can be repeated. For example, a SiN layer 352 is formed over the CdTe layer 306′, and a mask layer 354 is formed over the SiN layer 352. An opening 356 is formed through the mask layer 354, the SiN layer 352, and the CdTe layer 306′. In some cases, the mask layer 354 can represent a photoresist layer that is patterned to form the opening 356 in the mask layer 354. A dry etch or other etch can be used to etch through the SiN layer 352, and another dry etch or other etch can be used to etch through the CdTe layer 306′. This results in a portion of the HgCdTe layer 304 being exposed within the opening 356. Another implant 358 is formed in the HgCdTe layer 304 through the opening 356. In some embodiments, the implant 358 may represent a high-doped arsenic implant. In this example, the implant 358 is a narrower implant.

As shown in FIG. 3G, a cross-section 360 indicates that the SiN layer 352 and the mask layer 354 have been removed, such as by stripping. In some cases, the cross-section 360 may be produced after the structure undergoes an arsenic activation and a vacancy fill anneal. This results in the generation of an implant structure including the implants 322 and 358, which can have the same or similar form as the pixel implant geometry 200 described above. That is, the implant structure including the implants 322 and 358 can have a highly-doped pixel contact region at its center and a halo region around its periphery.

With reference to FIGS. 3F and 3G, although the implant 322 is shown as being wider than the implant 358, it should be noted that the implants 322 and 358 can be employed in a variety of other forms or sizes. For example, the implants 322 and 358 may be formed to have different depths. For example, the implant 358 can be slightly or significantly deeper than the implant 322, or the implant 322 can be slightly or significantly deeper than the implant 358. A combination of different widths and different depths can also be used with the implants 322 and 358.

Although FIGS. 3A through 3G illustrate examples of cross-sections of a high-performance photodetector during fabrication, various changes may be made to FIGS. 3A through 3G. For example, while specific materials and operations are provided above, a high-performance photodetector may be fabricated using any suitable materials and any suitable processing operations. Moreover, while the narrower implant is shown as being formed after the wider implant is formed, it is possible to reverse those operations and form the wider implant after the narrower implant is formed.

FIG. 4 illustrates an example method 400 for fabricating a high-performance photodetector according to this disclosure. For ease of explanation, the method 400 is described with respect to the pixel implant geometry 200 shown in FIG. 2. However, the method 400 may be used with any suitable pixel implant geometry designed in accordance with the teachings of this disclosure.

As shown in FIG. 4, a semiconductor substrate is obtained at step 402. This may include, for example, fabricating or otherwise obtaining a silicon or other semiconductor substrate 202. The semiconductor substrate 202 can include at least one additional layer 204, such as an HgCdTe layer, over the silicon or other semiconductor material.

A first implantation is performed to form a first doped region of the substrate at step 404. This may include, for example, using the process illustrated in FIGS. 3A through 3G to form the implant 206 in the additional layer 204 of the semiconductor substrate 202. A second implantation is performed to form a second doped region of the substrate at step 406. This may include, for example, using the process illustrated in FIGS. 3A through 3G to form the implant 208 in the additional layer 204 of the semiconductor substrate 202.

Fabrication of a photodetector is completed at step 408. This may include, for example, performing activation and annealing processes to form a completed implant in the semiconductor substrate 202. This may also include forming an electrically-conductive trace or other structure in electrical contact with the completed implant. This may further include fabricating any additional structures associated with the photodetector in or over the semiconductor substrate 202.

Although FIG. 4 illustrates one example of a method 400 for fabricating a high-performance photodetector, various changes may be made to FIG. 4. For example, while shown as a series of steps, various steps in FIG. 4 may overlap or occur in a different order. As a particular example, steps 404 and 406 may be reversed so that the second implant 208 is formed before the first implant 206.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a semiconductor substrate; and
a pixel formed in or over the semiconductor substrate, the pixel comprising:
a first implant having a first doping concentration; and
a second implant within the first implant, the second implant having a different width and/or depth than the first implant and a second doping concentration higher than the first doping concentration.

2. The apparatus of claim 1, wherein the pixel further comprises one or more ohmic contacts.

3. The apparatus of claim 1, wherein the second doping concentration provides ohmic contact for the pixel.

4. The apparatus of claim 1, wherein the first implant is configured to assist carrier collection, maintain quantum efficiency, and improve modulation transfer function (MTF) performance of the pixel.

5. The apparatus of claim 1, wherein dimensions of the first and second implants are selected to tailor an electric field profile within the pixel.

6. The apparatus of claim 1, wherein dimensions of the pixel are selected to reduce generation-recombination (GR) currents within the pixel.

7. The apparatus of claim 1, wherein dimensions of the pixel are selected to reduce a depletion size and a depletion magnitude of the pixel.

8. A system comprising:
a focal planar array comprising multiple pixels, wherein each of at least some of the pixels comprises:
a semiconductor substrate; and
a pixel formed in or over the semiconductor substrate, the pixel comprising:
a first implant having a first doping concentration; and
a second implant within the first implant, the second implant having a different width and/or depth than the first implant and a second doping concentration higher than the first doping concentration.

9. The system of claim 8, wherein each of the at least some of the pixels further comprises one or more ohmic contacts.

10. The system of claim 8, wherein, for each of the at least some of the pixels, the second doping concentration provides ohmic contact for the pixel.

11. The system of claim 8, wherein, for each of the at least some of the pixels, the first implant is configured to assist carrier collection, maintain quantum efficiency, and improve modulation transfer function (MTF) performance of the pixel.

12. The system of claim 8, wherein, for each of the at least some of the pixels, dimensions of the first and second implants are selected to tailor an electric field profile within the pixel.

13. The system of claim 8, wherein, for each of the at least some of the pixels, dimensions of the pixel are selected to reduce generation-recombination (GR) currents within the pixel.

14. The system of claim 8, wherein, for each of the at least some of the pixels, dimensions of the pixel are selected to reduce a depletion size and a depletion magnitude of the pixel.

15. A method of forming a pixel, the method comprising:
obtaining a semiconductor substrate;
performing a first implantation to form a first doped region of the substrate; and
performing a second implantation to form a second doped region of the substrate;
wherein the second doped region is positioned within the first doped region after formation of the doped regions;
wherein the first doped region has a different width and/or depth than the second doped region; and
wherein the second doped region has a higher doping concentration than the first doped region.

16. The method of claim 15, further comprising:
forming one or more ohmic contacts for the pixel.

17. The method of claim 15, wherein the doping concentration of the second doped region provides ohmic contact for the pixel.

18. The method of claim 15, wherein the first implant is configured to assist carrier collection, maintain quantum efficiency, and improve modulation transfer function (MTF) performance of the pixel.

19. The method of claim 15, wherein dimensions of the first and second implants are selected to tailor an electric field profile within the pixel.

20. The method of claim 15, wherein dimensions of the pixel are selected to reduce generation-recombination (GR) currents within the pixel.
